(19) United States
(12) Patent Application Publication
(10) Pub. No.: US 2020/0248300 A1
(43) Pub. Date: Aug. 6, 2020

(54) METHOD FOR NANOMODULATING METAL FILMS BY MEANS OF HIGH-VACUUM CATHODE SPUTTERING OF METALS AND STENCILS

(71) Applicant: Universidad de Santiago de Chile, Santiago (CL)

(72) Inventors: Juan Luis Palma Solorza, Santiago (CL); Juan Eduardo Escrig Murua, Santiago (CL); Juliano Casagrande Denardin, Santiago (CL)

(73) Assignee: Universidad de Santiago de Chile, Santiago (CL)

(21) Appl. No.: 15/774,482

(22) PCT Filed: Nov. 7, 2016
(86) PCT No.: PCT/CL2016/050059

§ 371 Date: May 8, 2018

(30) Foreign Application Priority Data
Nov. 9, 2015 (CL) 3277-2015

(51) Int. Cl. C23C 14/34; G11B 7/26; C25D 11/04; H05K 3/12

(52) U.S. Cl. CPC C23C 14/34; H05K 3/1225; C25D 11/04; G11B 7/266

(57) ABSTRACT

The present invention relates to a method for nanomodulating metal films by means of high-vacuum cathode sputtering of metals, and to stencils of anodized Al. As an example of the use of these nanomodulated metal films, the synthesis or production of a magnetically weak film by means of cathode sputtering, which film can he used as a magnetic field sensor, and a metal nanomodulated stencil are analyzed.

### FIELD OF THE INVENTION

The present invention relates to a method of nanomodulation of metallic films by sputtering of metal under high vacuum and Al anodized templates. As an example of use of these nanomodulated metal films, synthesis or obtaining a soft magnetic film by sputtering is analyzed—which can be used as magnetic field sensor, and a metal nanomodulated template.

### BACKGROUND OF THE INVENTION

Several manufacturing techniques for generating nanopatterns surfaces have been intensively investigated in recent years. Although the planar substrates are widely implemented in various applications (A. Barlow Elshabini and FD, Thin Film Technology Handbook (McGraw-Hill, New York, 1997]], there are numerous advantages of using curved surfaces as substrate (M. Albrecht, G. Hu, I L Guhr, T C Ulbrich, J. Boneberg, P. G. Leiderer and Schatz, Nature Mater. 4, 203 (2005]]. The curved surfaces alter the magnetic properties of the deposited system, including magnetic anisotropy which is a key factor in determining the magnetization reversal process. Moreover, the self-assembled and self-organizing materials have become an alternative suitable and cheapest route, compared with lithographic techniques, for manufacture of large-area patterned magnetic structures. As scalability, low cost, and manufacturing scale are critical points for applications such as high-density data storage or in sensors technology, these self-organized materials have been intensively studied.

On the one hand, densely packed two-dimensional arrays of monodisperse spherical polystyrene particles have been used as substrates to deposit multilayer films of Co/Pd (M. Albrecht, G. Hu, I L Guhr, T C Ulbrich, J. Boneberg, P. Leiderer and G. Schatz, Nature Mater. 4, 203 (2005) and T C Ulbrich, D. Makarov, G. Hu, I L Guhr, D. Suess, T. Schrefl and M. Albrecht, Phys. Rev. Lett. 96, 077202 (2006)) and Co/Pt (T. Eimuller, T C Ulbrich, E. Amaladass, I L Guhr, T. Tyliszczak and M. Albrecht, Phys. Rev. B 77, 134415 (2008)), while has been used as a substrate for depositing multilayers of Fe/Gd nanospheres to a monolayer of silica (E. Amaladass, B. Ludescher, G. Schutz, T. and T. Tyliszczak Eimuller, Appl. Phys. Lett 91, 172514 (2007) and E. Amaladass, B. Ludescher, G. Schutz, T. Tyliszczak, M.-S. Lee and T. Eimuller, J. Appl. Phys. 107, 053911 (2010)). The so-formed nanostructures are monodisperse, magnetically isolated, single-domain, and reveal a magnetic anisotropy induced by their spherical shape. Furthermore, Briones et al. (J. Briones, P. Bull, A. Holm, L. Knight, J C Denardin, F. Melo, E. Cerda, Robert S., D. F. and Montaigne Lacour, Appl. Phys. Lett. 103, 072404 (2013)) have studied a Co film deposited on a wrinkled polydimethylsiloxane (PDMS) elastomeric layer evidencing a submicrometer lateral modulation. They also confirmed the uniaxial nature of the anisotropy and observed a reversal mechanism more complex than pure coherent rotation.

Another alternative means to achieve nanopatterned media is the use of anodized Al templates. Rosa et al. (W O Rosa, M. Jaafar, Asenjo A. and M. Vázquez, Nanotechnology 20, 075301 (2009) and W O Rosa, M. Jaafar, Asenjo A. and M. Vázquez, J. Appl. Phys. 105, 07C108 (2009)) have used these templates (with controlled geometry) as a precursor for replication of its ordering into a polymer surface (polymethyl methacrylate—.PMMA]. Furthermore, they have sputtered a Co thin film on the polymer surface to finally obtain a nanohill Co/PMMA composite. Additionally, they have sputtered Cu and Cr capping layers onto the Co film (W O Rosa, L. Martinez, M. Jaafar, Asenjo A. and M. Vázquez, J. Appl. Phys. 106 , 103906 (2009)). However, in all cases they observed the presence of an intrinsic distribution of magnetic anisotropy and the identification of single or multidomain structures inside Co depending on the controlled periodicity of the nanostructured Al template.

Although these studies on large-area patterned magnetic structures modeled on large-areas patterned magnetic structures, all of them considered Co films, which are especially interesting because of its large magnetocrystalline anisotropy that favors in many cases a perpendicular-to-the axis easy magnetization axis for the hcp equilibrium phase (J. Cho, J. Hyun, J H Wu, S P Min, Ko J Y, Kim Y K and Q X Soh, J. Magn. Magn. Mater. 303, E281 (2006) and Y P Ivanov, L G Vivas, A. Asenjo, A. Chuvillin O. Chubykalo-Fesenko and M. Vázquez, Europhys. Lett 102, 17009 (2013)). However, there is no publication which relates to a soft magnetic film on ordered metallic nanohills, in order to determine the effect only the shape anisotropy of magnetic properties. For example, the Ni-Fe containing about 50-80% nickel, known generically as Permalloy, is known for a century and is used in various electronic devices. Additions molybdenum, copper or chromium, alone or in combination, can increase the resistivity (compared with Permalloy) and with proper annealing treatment (about 500 Q C), both anisotropy and magnetostriction can be simultaneously brought to zero (A T Inglés and G Y Chin, J. Appl. Phys. 38, 1183 (1967) and F. C. and Pfeifer Radeloff, J. Magn. Magn. Mater. 19, 190 (1980)). Such materials are usually called Supermalloy, have a high magnetic permeability (120000) (A T Inglés and G Y Chin, J. Appl. Phys. 38, 1183 (1967) and J. Ma, M. Qin, X. Wang, L. Zhang, L. Tian, X. Zhang, X. Li and X. Qu, Powder Technology 253, 158-162 (2014)) and a low coercivity, and thus represent the solution for applications where excellent magnetic properties (B V Neamtu, Chicinas I., O. Isnard, I. Ciascai, F. Stern and required T F Marinea, J. Magn. Magn. Mater. 353, 6 (2014)). It is well known that metal films are involved in a wide range of applications in microelectronics, creating devices, machinery, (medical or technical) instrumentation, utensils etc. One reason why copper or silver used for utensils is their bactericidal properties, which are enhanced when they are in the form of nanoparticles, and an increase occurs in the contact surface of the metal. Thus, an alternative to improve the properties of the metal films is modulating them. However, as noted above, there is only nanomodulated polymer (specifically polymethylmethacrylate, PMMA), for which first a template aluminum is obtained with nanovalleys. On this template the polymer is applied in specific. At cure polymer, it hardens and remains rigid. The next step is to remove aluminum metal by etching. By immersing this structure in a solution (0.10 M CuCb, 20% v/v HCl] which dissolves only metallic aluminum, then obtaining the remaining polymer in the recorded over the entire surface of the polymer nanodomes. If using the same procedure the polymer for metal would be replaced, it will instantly bond two metals together, which cannot be off one after the execution of the method, because when the etching is performed to dissolve the metal, both metals dissolve.

The proposed method in the present invention does not require separate template/mold from the surface by dissolving through chemical attack one of the metals. By contrast, the present method comprises separating the template/mold from the nanomodulated surface by low-adhesion deposition, allowing off the template aluminum nanodomes to the metal surface which is being modulated, with the additional advantage that the mold (template Al nanostructured) is not damaged, so it can be reused as often as necessary. Thus, the present method permits to obtain a nonomodulated metallic film of copper, gold or silver, and also allows reuse of the mold multiple times, allowing to reach a modulation which extends over the entire surface, and ensures complete coating.

### BRIEF DESCRIPTION OF THE INVENTION

This method uses Al templates etched by nanovalleys for nanomodulation of metallic film by soft printing. On the aluminum templates nonmagnetic metal film of copper, gold or silver are deposited by sputtering technique under high vacuum (known as Sputtering) which exhibits low adhesion due to the conditions used during deposition. This allows removing said non-magnetic metal film from the aluminum template recorded with nanovalleys, thereby obtaining a metal film recorded with nanodomes. Importantly, the method of the present invention requires no dissolving by chemical attack the aluminum template recorded with nanovalleys, so it is not damaged and can be re used as often as necessary.

This method allows to obtain a non-magnetic metal nanomodulated film of copper, gold or silver, wherein said non-magnetic metal film reaches a modulation extending across the surface of the film, and ensures complete coating. It also allows reuse multiple times, an aluminum template with nanovalleys.

The morphology of these specific modulated films by scanning electron microscopy (SEM) using apparatus EVO MA10, confirms that the nonmagnetic metallic material reproduces the template pattern. In addition, a fairly regular hexagonal arrangement of nanodomes can be observed (see FIG. 2B).

These nonmagnetic nanomodultaed metallic films are used as substrates on which are deposited supermalloy thin films (an alloy of 80% Ni, 5% Mo and Mn and balance Fe). It can be seen that the superalloy film adopts the topology imposed by to substrate (in this case, the nanomodulated metallic nonmagnetic film], and thus, the arrangement of the anodized aluminum arrangement template after coating and replication processes.

Finally, the magnetic behavior of these thin superalloy films at room temperature was also studied and found that when the external magnetic field is applied perpendicular to the substrate, the coercivity increases linearly with increasing radius of nanodomes. These soft magnetic films are used in magnetic field sensors.

Thus, the present invention relates to a method of nanomodulation of metallic film by metal sputtering under high vacuum and anodized Al templates. As an example of use of these nanomodulated metal surfaces, the synthesis of a soft magnetic film by sputtering and a metal nanomodulated template is analyzed.

### BRIEF DESCRIPTION OF THE FIGURES

FIG. 1. Scheme for obtaining a nanomodulated nonmagnetic metal film, and coated with a magnetic material (eg, Supermalloy) potential application from top left and following the flowchart; high purity aluminum (1), by an anodizing process a film of porous alumina (2) is obtained by eliminating aluminum oxide aluminum film with nanovalleys is obtained, using the method of the present invention, a non-magnetic metal is deposited (3) with a high deposition rate, then the nonmagnetic metal is peeled from the aluminum film with nanovalleys (due to its low adhesion), and then a thin film of magnetic material (4) is deposited.

FIGS. 2A, 2B, 2C and 2D: FIG. 2A shows a geometric description of the side of a nanostructured magnetic film on a substrate of non-magnetic metal nanodomes view. FIG. 2B shows a SEM picture of a silver film with nanodomes radius r=155 nm and a center to center distance D=321 nm. FIG. 2C shows an SEM image of a film on nanodomes of nanostructured silver supermalloy ordered with radius r=60 nm and the center to center distance D=150 nm. 2D shows an SEM image of a film on nanodomes nanostructured silver supermalloy ordered with radius r=155 nm and distance center to center D=321 nm.

FIGS. 3A and 3B: Magnetic properties of nanostructured supermalloy film having a radius r=55 nm and a center to center distance D=135 nm. FIG. 3A shows hysteresis curves when the external magnetic field is applied in the plane of the substrate to a smooth film (triangles) and Supermalloy nanostructured film (squares). FIG. 3B shows hysteresis curves when the field external magnetic applied perpendicular to the substrate to a smooth film (triangles) and Supermalloy nanostructured film (square), (b subgraph) approach hysteresis curves at low values of applied magnetic field to observe the coercivity (width of the hysteresis curve) and remanence (magnetization when the external field is zero).

FIGS. 4A and 4B: FIG. 4A shows the coercivity for Supermalloy nanostructured films on nanodomes sorted as a function of radius r, where the external magnetic field is applied parallel (circles) and perpendicular (square) to the substrate. FIG. 4B shows the magnetization. Supermalloy remaining for nanostructured films on nanodomes sorted as a function of radius r, where the external magnetic field is applied parallel (circles) and perpendicular (square) to the substrate.

### DETAILED DESCRIPTION OF THE INVENTION

The present invention relates to a method of nanomodulation to metal surface by metal sputtering under high vacuum and anodized Al templates. As an example of use of these nanomodulated metal surfaces, the synthesis of a soft magnetic film by sputtering and a metal nanomodulated template is analyzed.

Aluminum templates recorded with nanovalleys for nanomodulation metal surface by soft printing used in the present method. On templates aluminum is deposited by the sputtering technique under high vacuum (known as Sputtering), a non-magnetic metal film of copper, gold or silver, which exhibits low adhesion due to the conditions used during the deposit. This allows removal of the non-magnetic metal film from the recorded nanovalleys aluminum template, thereby obtaining a metal film recorded with nanodomes.

In the method of the present invention it is not required dissolving by chemical attack the template recorded with aluminum nanovalleys, so it is not damaged and can be reused as often as necessary.

This method allows to obtain a non-magnetic nanomodultaed metal film of copper, gold or silver, where the non-magnetic metal film reaches a modulation extending across the surface, and ensures complete coating.

The morphology of these specific modulated films by scanning electron microscopy (SEM) using apparatus EVO MA10, confirms that the nonmagnetic metallic material reproduces the template pattern. In addition, a fairly regular hexagonal arrangement of nanodomes was observed (see FIG. 2B). As an example application, these nonmagnetic nanomodulated metal surfaces are used as substrates on which are deposited thin Supermalloy films (an alloy of 80% Ni, 5% Mo and Mn and balance Fe). It can be seen Supermalloy that the film adopts the topology imposed by the substrate (in this case, the non-magnetic nanomodulated metal film), and thus, the arrangement of aluminum anodized template after coating and replication processes.

Finally, the magnetic behavior of these thin supermalloys films at room temperature was also studied and found that when the external magnetic field is applied perpendicular to the substrate, the coercivity increases linearly with increasing radius of nanodomes. These soft magnetic films are used in magnetic field sensors.

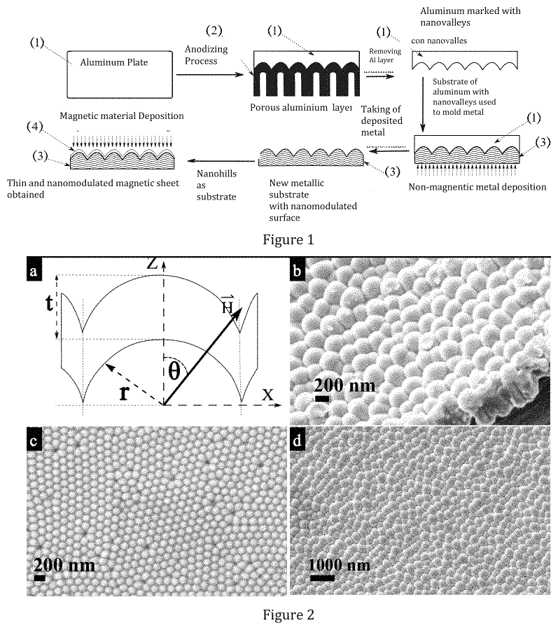

This method comprises the following steps (see FIG. 1):

a) Obtaining an aluminum template with nanovalleys: an aluminum film of high purity is anodized for 6 hours, which consists of a natural layer of aluminum oxide (known as alumina) very thin on the surface then anodizing it becomes growing the thin oxide layer of said film by an electrochemical method, where the electrolyte solution—as defined in the following paragraph, used partially dissolve the alumina, and then, a porous layer is formed, which continues sustained on aluminum, To remove the layer of porous alumina, a selective chemical attack using an acid solution is performed—as defined in the subsequent paragraph this attack affects only the alumina and leaves intact the aluminum. By removing this porous aluminum oxide layer an aluminum substrate with semicircular holes which are hexagonally arranged is obtained. This is what has been termed “template aluminum recorded with nanovalleys”.

Electrolyte solutions are those that are commonly used for anodizing aluminum, sulfuric acid (H₂SO₄], oxalic acid (H₂C₂O₄] and phosphoric acid (H₃PO₄], having a concentration of 0.3M and the voltage range used in each case: 25-35, 40-60 and 170-190 V, respectively, depending on the conductivity of each acid medium.

The temperature under which the oxide layer grow is in the range 0-2° C., to avoid localized concentrations of heat are generated. In addition, the oxides are more clear when this temperature is used compared to when a higher temperature between 20-25° C. is used where a more opaque membrane is obtained. However, the advantage of raising the temperature is that it provides a faster growth.

The acid solution used to remove the oxide layer is a mixture of 1.8 g of chromic acid (CrC), 7 g of phosphoric acid (H₃PO₄) and completed with H₂O reaching 100 ml. The time taken to dissolve this layer it is proportional to anodizing time. The speed with which the oxide layer of the first anodizing is dissolved depends on the temperature at which the acid is maintained, usually between 35 and 45° C.

Thus, a substrate of aluminum metal, which is embossed with semicircular nanovalleys hexagonally arranged, whose geometric parameters are defined by the parameters of the anodizing process (acid used, concentration, voltage, temperature, etc.] is obtained.

b) Nanomodulation of a nonmagnetic metallic film: Once obtained the aluminum film with nanovalleys, a nonmagnetic metal is evaporated thereon to generate a metal film then lift off. Evaporation of nonmagnetic metal deposited, is made with the high vacuum magnetron sputtering technique (known as Sputtering]. The evaporated metal adopts the structure of aluminum nanovalleys. To ensure low adhesion of non-magnetic metal deposited on the nanostructured aluminum, very high rate of deposition, between 59 and 127 nm/min, which is different for each of the metals vaporized, is used. This deposition rate is obtained using an approximate distance of 5 cm between the barrel and substrate, which is a small distance compared to the commonly used (15 to 20 cm). In addition, the fact that the samples are very close to the spray gun produces heating also prevents good adhesion of the layer metal deposited on the substrate.

Nanomodulated Gold Film (Au).

To evaporate gold on the aluminum film with nanovalleys, the parameters used are: prevacuum chamber 0.15×10⁶ mbar, argon flow of 15 sccm, a pressure of 6.67×10³ mbar and power of 50 W. with these parameters gold was deposited for 900 s to obtain a thickness of 885 nm, corresponding to a deposition rate of 59 nm/min.

Nanomodulated Copper Film (Cu).

To evaporate copper on the aluminum film with nanovalleys, the parameters used are: prevacuum chamber 0.15×10⁶ mbar, argon flow of 20 sccm, a pressure of 6.67×10³ mbar and power of 50 W with these parameters, copper was deposited over a period of 600 s to obtain a thickness of 912 nm, corresponding to a deposition rate of 91 nm/min.

Nanomodulated fAgl Silver Film.

To evaporate silver on the aluminum film with nanovalleys parameters used are: prevacuum chamber 6.67×10⁶ mbar, argon flow of 15 sccm, a pressure of 6.67×10³ mbar and a power of 50 W. With these parameters silver was deposited for a period of 300 s to obtain a thickness of 633 nm, corresponding to a deposition rate of 127 nm/min.

c) To remove the nonmagnetic metallic film substrate: For this it is only necessary to remove the metal film deposited on the aluminum substrate with nanovalleys. It can be removed more easily the nonmagnetic metallic film from the aluminum template placing an adhesive (for example, tape or double-sided tape] on the deposited non-magnetic metal film. The low adhesion between metals allows, once the adhesive means is removed, that the non-magnetic metal foil glued keeps the adhesive means separating this way from nanoestructured aluminum template. Table 1 shows different geometrical parameters of the domes which are printed on the metal surface magnetic.

TABLE 1
Geometric Parameters for Supermalloy
nanostructured films on ordered
metal nanodomes. The data show the radius, r, of
non-magnetic metal domes (Ag), the
center to center distance, D, between them,
and the thickness, t, of the magnetic material
(Supermalloy) deposited on the
nanomodulated nonmagnetic metallic film.

| r (nm) | D (nm) | t (nm) |
|---|---|---|
| 25 | 58 | 60 |
| 25 | 73 | 60 |
| 55 | 135 | 60 |
| 60 | 150 | 60 |
| 155 | 321 | 60 |

FIG. 2 (b) shows the morphology of a surface of silver (Ag) with nanodomes of radius r=155 nm and a center to center distance between them of D=321 nm. From the figure it is apparent that the metallic material magnetic reproduces the pattern of the template aluminum.

The morphology of the film of interest comprises a non-magnetic metal film on one of its main faces containing solid hemispheres arranged in hexagonal arrays. The hemispheres are with its flat face attached to the surface. The hexagonal arrangement is perfect in sections comprising 1 to 2 micrometers in diameter. Hemispheres, called nanodomes, extend throughout the metal surface, and there is a section that does not contain them (see FIG. 2B).

The diameters of the areas are determined by the spacing between the pores, determined by the potential V, which is obtained when occurring the anodizing process of aluminum template. Meanwhile, the potential V which can be applied at the time of anodization is determined by the conductivity of the electrolyte being used, which can come from sulfuric acid (H₂SO₄), oxalic acid (H₂C₂O₄) and phosphoric acid (H₃PO₄).in this way, then depending on the acid solution used as electrolyte, it can handle a discrete diameters for each nanodome ranging between 20 and 500 nm range.

Nanomodulated metal films are likely candidates to improve and optimize the bactericidal effect of these films, because there is an increase in the surface compared to a smooth film. This increased surface makes more effective antibacterial treatment, even nanomodulation gives a surface, so to speak, “inconvenient” for some agents, i. e, does not facilitate their settlement on the surface, so that it can be used not only as a bactericidal surface, but also as a repellent surface.

Moreover, these non-magnetic metal nanostructured films are used as substrates on which thin supermalloys films (80% Ni, 5% Mo and balance with Mn and Fe (HYMU 80] with 99% purity Kurt J Lesker Company) are deposited simultaneously for all substrates by sputtering using a base pressure of 9.6×10⁶ mbar and a working pressure for Ar+4.0×10³ mbar. The thickness of Supermalloy is about t=60 nm and also a layer of tantalum of 5 nm is deposited for protection. FIGS. 2C and 2D show the SEM images of the Supermalloy nanostructured films on ordered metal nanodomes with radii of 60 and 155 nm, respectively. As shown, the images reveal a fairly regular hexagonal arrangement of nanodomes. Furthermore, the supermalloy film deposited adopts the topology imposed by the substrate (in this case, the silver surface with nanodomes]. As the Supermalloy exhibits high permeability, contrary to what happens with cobalt, this material has a very small magnetocrystalline anisotropy, so that the shape anisotropy of these nanodomes is solely responsible for the changes observed on the magnetic properties of these nanostructures. Thus, these nanomodulated substrates add an extra degree of freedom for engineering magnetic behavior of a thin film by combining a nanometric topographical pattern with the deposition of a magnetic film.

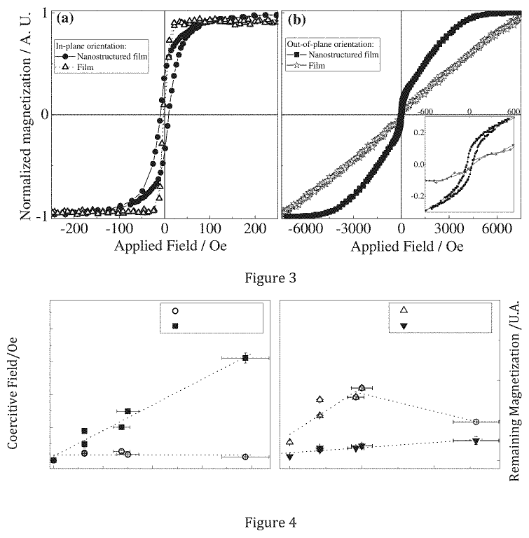

The magnetization curves were measured using a magnetometer force alternating gradient (AGFM, for its acronym in English) for an external oriented out of the plane (0 °) and the plane (90 °) Sample field. FIG. 3 shows the hysteresis curves of asupermalloy nanostrctured film of deposited on Ag-ordered nanodomes having a radius r=55 nm and a distance center to center D=135 nm. from FIG. 3A it can be seen that when the magnetic field is applied in the plane of the substrate (90 °), the sample shows an increase in coercivity compared with measured on a film not nanostructured and almost bistable compartment with a hysteresis curve square, where the rotation process magnetization occurs at low fields. In addition, when the applied external field outside the plane of the substrate (Oo), the hysteresis curve is saturated with a nearby external magnetic field at 7 kOe, and it exhibits an S-shape, with a greater comparative coercivity relative to the hysteresis curve measured in the plane. This is due to the existence of an out of plane component of the magnetization associated with the geometry of the samples.

To investigate the effect of shape anisotropy on the magnetic properties of supermalloy nanostructured films about Ag-ordered nanodomes, the variation of the coercivity is shown (see FIG. 4A) and remanence (see FIG. 4B) as a function of radius r the nanodomes. As the thickness of the deposited magnetic film is constant for all investigated samples (t=60 nm), the observed differences in the magnetic properties correspond only to the shape of the Ag nanodomes on which the magnetic material is deposited. Thus, when the magnetic field is applied in the plane of the substrate (90°), the coercivity remains constant independent of the radius r (size) of nanodomes. This indicates that if a parallel external magnetic field is applied to the film plane its coercivity not vary with the existence of small modulations or ridges on it. This point is extremely interesting because allows using a real thin film (rugose) for potential applications. In addition, the remanence exhibits a non-monotonic behavior. As the radius increases, the remanence increases to a maximum value for r=60 nm, on which further increases in the radius imply a decrease in remanence. This effect arises because the magnetostatic interaction between nanodomes and disorder. Moreover, when the magnetic field is applied outside the plane of the substrate (0°), the coercivity increases linearly with the radius r of nanodomes increases. In addition, the coercivity varies between 0 and 120 Oe simply varying the radius r of the nanodomes. It is noteworthy that r=0 nm corresponds to a flat film. The variation in coercivity is because by varying the radius of nanodomes also increases its height, thus modifying the shape anisotropy of the thin film. In practical terms, the variation in the radius of nanodomes induces a perpendicular growth on the flat film (increasing the thickness of the thin film), which contributes to magnetization out of the plane. Finally, it is important to note that the remanence remains constant when the magnetic field is applied perpendicular to the substrate, regardless of the radius of nanodomes.

The magnetic film deposited on the substrate nanodomes took the form of the substrate, and thus, the magnetic film was nanomodulated. This modulation in the magnetic film induces a magnetic anisotropy out of the plane. This type of anisotropy is critical in high density magnetic recording. Furthermore, it is concluded that the perpendicular magnetic coercivity of nanomodulated film increases with the radius of nanodome as an individual element. Moreover, the anisotropy magnetic films with out of plane can be used as high density magnetic memories. The storage capacity of the memories based on perpendicular systems to the recording surface, provide a much higher capacity recording, which could increase from LGB/in 2 to LTB/in 2 based memories recording plane, where these latter are those used today. Based on this point it is that substrates with modulated nanodomes to synthesize or obtain anisotropy magnetic thin films with out of plane metal surfaces were used.

What is claimed:

1. Method for nanomodulation of metal surfaces, comprising the following steps:
a) to obtain a template recorded with aluminum nanovalleys, anodizing a high-purity aluminum film consisting of a natural oxide layer very thin of aluminum on its surface, growing said layer by using an electrochemical solution to partially dissolve the oxide aluminum and form a porous layer is supported on the aluminum, which is removed by selective chemical attack with an acidic solution, to thereby obtaining aluminum with semicircular holes arranged hexagonally, and then obtaining an aluminum substrate metal which is recorded with semicircular nanovalleys hexagonally ordered;
wherein said electrolytic solution is selected from sulfuric acid (H₂SO₄), oxalic acid (H₂C₂O₄) or phosphoric acid (H₃PO₄), and said acid solution is a mixture of chromic acid (CrOs), phosphoric acid (H₃PO₄9 and H₂0;
b) nanomodulating a metal film using aluminum substrate recorded with nanovalleys obtained in step a), by evaporating onto said substrate a metal selected from the group consisting of Au, Cu or Ag to generate a metal film then take off, and where evaporation of metal is deposited, it is performed by sputtering in a high vacuum, and the metal evaporated adopts the structure of aluminum nanovalleys, and where to ensure low adhesion of metal deposited on the nanostructured aluminum is used a deposition rate very high, between 59 and 127 nm/min and also a distance of approximately 5 cm between the barrel and the substrate is used;
c) removing the foil substrate by simply removing the foil deposited aluminum substrate nanovalleys.

2. The method of claim 1, wherein said acid solution having a concentration of 0.3 M and applied under a potential (V) with a voltage range between 25-190 V.

3. The method of claim 2, wherein said electrolytic solution is sulfuric acid (H₂SO₄) is applied under a potential (V) with a voltage range between 25-35 V.

4. The method of claim 2, wherein said electrolytic solution is oxalic acid (H₂C₂O₄) is applied under a potential (V) with a voltage range between 40-60 V.

5. The method of claim 2, wherein said electrolyte solution is phosphoric acid (H₃PO₄) and is applied under a potential (V) with a voltage range between 170-190 V.

6. The method of claim 1, wherein the temperature at which the oxide layer is grown is in the range between 0-2° C.

7. The method of claim 1, wherein said acid used to remove the oxide layer is a mixture of 1.8 g of chromic acid (CrOs), 7 g of phosphoric acid (H₃PO₄) and H₂O to reach 100 ml.

8. The method of claim 7, wherein said acid is used at a temperature between 35 and 45° C.

9. The method of claim 1, wherein for evaporating gold on the aluminum foil with nanovalleys previously is evacuated 0.15×10⁶ mbar in the chamber, and then an argon flow of 15 sccm is used, a pressure of 6.67×10³ mbar and a power of 50 W, and allowed to deposit the gold for 900 s to obtain a thickness of 885 nm.

10. The method of claim 1, wherein for evaporating copper on aluminum foil nanovalleys previously is evacuated to 0.15×10⁶ mbar in the chamber, and then flow 20 sccm of argon is used, a pressure of 6.67×10³ mbar and a power of 50 W, and allowed to deposit copper for a period of 600 s, obtaining a thickness of 912 nm.

11. The method of claim 1, wherein for evaporating silver on the aluminum foil with nanovalleys previously is evacuated of 6.67×10⁶ Torr in the chamber and an argon flow of 15 sccm is used, a pressure 6.67×March 10⁶ Torr and a power of 50 W, and allowed depositing silver over a period of 300 s, obtaining a thickness of 633 nm.

12. The method of claim 1, wherein in step c) optionally an adhesion means used, including an adhesive tape or an adhesive double sided tape, which is incorporated planar substrate on the side opposite to the deposition of metal.

13. nanostructured metal films by nanodomes sorted, wherein the solid hemispheres nanodomes are arranged in hexagonal arrays, and the radius of nanodomes is in the range of 25-155 nm, the center to center distance to nanodome-nanodome is in the range of 55-325 nm and the film thickness is 60 nm.

14. The film of claim 13, wherein the hexagonal arrangements are perfect in sections comprising between 1 and 2 micrometers long, and the hemispheres or nanodomes extend throughout the metal surface, and there is a section that does not contain them.

15. Use of the film of claims 13 to 14, as magnetic field sensors.
